(19) United States
(12) Patent Application Publication
(10) Pub. No.: US 2026/0279469 A1
(43) Pub. Date: Sep. 17, 2026

(54) ML EQUALIZER DEVICES FOR DE-NOISING INTERFERENCE BASED ON PROGRAMMING PULSE READ VOLTAGES AND POST-ERASURE VOLTAGES

(71) Applicant: Samsung Electronics Co., Ltd., Suwon-si (KR)

(72) Inventors: Karen MICHAELI, Tel-Aviv (IL); Amir SARAF, Giv'atayim (IL); Dori REICHMANN, Jerusalem (IL); Evgeny BLAICHMAN, Tel-Aviv (IL); Jonathan ZEDAKA, Jerusalem (IL); Amit BERMAN, Binyamina (IL)

(73) Assignee: Samsung Electronics Co., Ltd., Suwon-si (KR)

(21) Appl. No.: 19/081,123

(22) Filed: Mar. 17, 2025

(51) Int. Cl. G11C 16/34; G11C 16/04

(52) U.S. Cl. CPC G11C 16/3404; G11C 16/0483

(57) ABSTRACT

An equalizer device including processing circuitry configured to cause the equalizer device to detect a post-retention voltage of a target memory cell and at least one retention feature, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased, generate a pre-retention voltage estimate of the target memory cell by inputting the post-retention voltage and the at least one retention feature into a trained machine learning algorithm, and recover data stored to the target memory cell based on the estimated pre-retention voltage.

### FIELD OF THE DISCLOSURE

Some example embodiments provide devices, systems, methods, and non-transitory computer-readable media for correcting errors in data corrupted by retention effects using programming pulse read voltages and/or post-erasure voltages.

### BACKGROUND

Error Correction Codes (ECCs) are used for detecting and correcting errors in data that has become corrupted. For example, parity bits are generated corresponding to target data to be protected. When recovering the target data, corrupted bits within the target data are detected and corrected using the parity bits. For instance, the parity bits are used to detect a position of an erroneous bit within the target data, and the erroneous bit is corrected by inverting a logic value of the erroneous bit.

### SUMMARY

Some example embodiments provide improved systems, methods, and non-transitory computer-readable media for correcting errors in data corrupted by retention effects using programming pulse read voltages and/or post-erasure voltages.

Some example embodiments provide an equalizer device including processing circuitry configured to cause the equalizer device to detect a post-retention voltage of a target memory cell and at least one retention feature, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased, generate a pre-retention voltage estimate of the target memory cell by inputting the post-retention voltage and the at least one retention feature into a trained machine learning algorithm, and recover data stored to the target memory cell based on the estimated pre-retention voltage.

Some example embodiments provide a storage device including a memory including a plurality of memory cells, and processing circuitry configured to cause the storage device to detect a post-retention voltage of a target memory cell and at least one retention feature, the target memory cell being among the plurality of memory cells, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased, generate a pre-retention voltage estimate of the target memory cell by inputting the post-retention voltage and the at least one retention feature into a trained machine learning algorithm, and recover data stored to the target memory cell based on the estimated pre-retention voltage.

Some example embodiments provide a storage system including a host configured to output a command to read a target memory cell, a memory including a plurality of memory cells, the plurality of memory cells including the target memory cell, and processing circuitry configured to cause the storage system to detect a post-retention voltage of a target memory cell and at least one retention feature in response to the command, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased, generate a pre-retention voltage estimate of the target memory cell by inputting the post-retention voltage and the at least one retention feature into a trained machine learning algorithm, and recover data stored to the target memory cell based on the estimated pre-retention voltage.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For the purposes of clarity, various dimensions of the drawings may have been exaggerated.

FIG. 1 illustrates a block diagram of a host storage system 10, in accordance with some example embodiments;

FIG. 2 illustrates a block diagram of a memory device 300, according to some example embodiments;

FIG. 3 illustrates a diagram of a 3D V-NAND structure, according to some example embodiments;

FIG. 4A illustrates a detailed diagram of the ECC engine 217, according to some example embodiments;

FIG. 4B illustrates a diagram of the ECC encoding circuit 510, according to some example embodiments;

FIG. 4C illustrates a diagram of the ECC decoding circuit 520, according to some example embodiments;

FIG. 5 illustrates a method of performing an error correction operation, according to some example embodiments;

FIG. 6 illustrates a block diagram of a host storage system implementing an ML algorithm, according to some example embodiments;

FIGS. 7A-7B illustrate graphical representations of example recurrent neural networks for implementing the ML algorithm 616, according to some example embodiments;

FIG. 8 illustrates graphical representations of example weak decision voltage ranges and hard decision voltage ranges, according to some example embodiments;

FIG. 9 illustrates a method for generating a correct (e.g., pre-retention) voltage threshold level of a memory cell using the plurality of threshold networks 1020, according to some example embodiments;

FIG. 10 illustrates a method for training the ML algorithm 616, according to some example embodiments;

FIG. 11 illustrates a method for recovering data stored to a target memory cell, according to some example embodiments;

FIG. 12 illustrates a method for recovering data stored to a target word-line based on the programming pulse read voltages and the neighbor voltages, according to some example embodiments; and

FIG. 13 illustrates a method for recovering data stored to a target word-line based on the post-erasure voltage and the neighbor voltages, according to some example embodiments.

### DETAILED DESCRIPTION

Error Correction Codes (ECCs) are used for detecting and correcting errors in data that has become corrupted. For example, ECCs may include parity bits generated based on target data that is to be protected. However, these parity bits are only capable of being used to detect and/or correct a set quantity of erroneous bits (e.g., 1 bit or 2 bits). Conventional devices and methods for retrieving target data using ECCs are unable to recover corrupted target data containing more than the set quantity or erroneous bits detectable and/or correctable by the parity bits corresponding to the corrupted target data. Accordingly, the conventional devices and methods result in excessive data loss (e.g., higher Bit Error Rate (BER)) and/or excessive resource consumption used in providing additional protection of the target data (e.g., mirroring in other storage, increasing the size of parity bits, etc.). However, according to example embodiments, improved devices and methods are provided for retrieving target data using ECCs that avoid or mitigate these disadvantages.

As would be understood by a person of ordinary skill in the art, ECCs may be used for detecting and correcting errors in data within the scope of many different types of implementation examples. The below discussion is mainly focused on addressing corruption to data stored in memory cells, but some example embodiments are not limited thereto, and the below discussion may also be applicable to other types of implementation examples (e.g., data transmitted via a noisy channel, etc.).

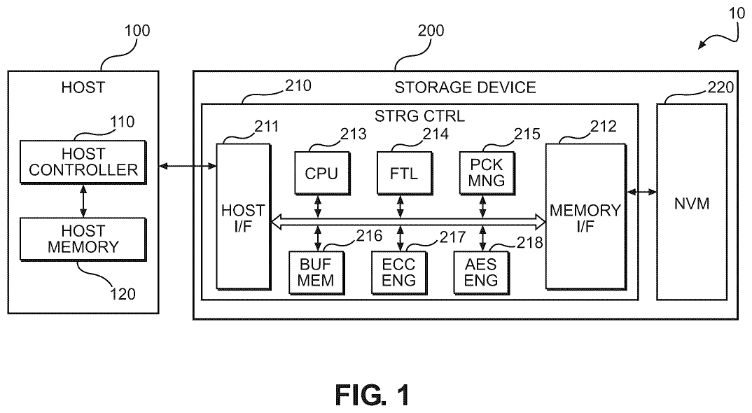

FIG. 1 illustrates a block diagram of a host storage system 10, in accordance with some example embodiments.

Referring to FIG. 1, the host storage system 10 may include a host 100 and/or a storage device 200. Further, the storage device 200 may include a storage controller 210 and/or a Non-Volatile Memory (NVM) 220. According to some example embodiments, the host 100 may include a host controller 110 and/or a host memory 120. The host memory 120 may serve as a buffer memory configured to temporarily store data to be transmitted to the storage device 200 and/or data received from the storage device 200.

The storage device 200 may include storage media configured to store data in response to requests from the host 100. As an example, the storage device 200 may include at least one of a Solid-State Drive (SSD), an embedded memory, and/or a removable external memory. When the storage device 200 is an SSD, the storage device 200 may be a device that conforms to an NVM Express (NVMe) standard. When the storage device 200 is an embedded memory or an external memory, the storage device 200 may be a device that conforms to a Universal Flash Storage (UFS) standard or an Embedded MultiMediaCard (eMMC) standard. Each of the host 100 and/or the storage device 200 may generate a packet according to an adopted standard protocol and transmit the packet.

When the NVM 220 of the storage device 200 includes a flash memory, the flash memory may include a two-dimensional (2D) NAND memory array or a three-dimensional (3D) (or vertical) NAND (VNAND) memory array. As another example, the storage device 200 may include various other kinds of NVMs. For example, the storage device 200 may include Magnetic Random Access Memory (MRAM), spin-transfer torque MRAM, Conductive Bridging RAM (CBRAM), Ferroelectric RAM (FRAM), Phase-change RAM (PRAM), Resistive RAM (RRAM), and/or various other kinds of memories.

According to some example embodiments, the host controller 110 and the host memory 120 may be implemented as separate semiconductor chips. According to some other example embodiments, the host controller 110 and the host memory 120 may be integrated in the same semiconductor chip (or similar semiconductor chips). As an example, the host controller 110 may be any one of a plurality of modules included in an application processor (AP). The AP may be implemented as a System on Chip (SoC). Further, the host memory 120 may be an embedded memory included in the AP, or an NVM or memory module located outside the AP.

The host controller 110 may manage an operation of storing data (e.g., write data) of a buffer region of the host memory 120 in the NVM 220 or an operation of storing data (e.g., read data) of the NVM 220 in the buffer region.

The storage controller 210 may include a host interface 211, a memory interface 212, and/or a CPU 213. Further, the storage controller 210 may further include a Flash Translation Layer (FTL) 214, a packet manager 215, a buffer memory 216, an Error Correction Code (ECC) engine 217, and/or an Advanced Encryption Standard (AES) engine 218. The storage controllers 210 may further include a working memory (not shown) in which the FTL 214 is loaded. The CPU 213 may execute the FTL 214 to control data write and read operations on the NVM 220. According to some example embodiments, the storage controller 210 may include additional components, or omit components, relative to those components discussed herein in connection with FIG. 1.

The host interface 211 may transmit and receive packets to and from the host 100. A packet transmitted from the host 100 to the host interface 211 may include a command and/or data to be written to the NVM 220. A packet transmitted from the host interface 211 to the host 100 may include a response to the command and/or data read from the NVM 220. The memory interface 212 may transmit data to be written to the NVM 220 to the NVM 220 or receive data read from the NVM 220. The memory interface 212 may be configured to comply with a standard protocol, such as Toggle or Open NAND Flash Interface (ONFI).

The FTL 214 may perform various functions, such as an address mapping operation, a wear-leveling operation, and/or a garbage collection operation. The address mapping operation may be an operation of converting a logical address received from the host 100 into a physical address used to store data in the NVM 220. The wear-leveling operation may be a technique for preventing (or reducing) excessive deterioration of a specific block by allowing blocks of the NVM 220 to be uniformly (or more uniformly) used. As an example, the wear-leveling operation may be implemented using a firmware technique that balances erase counts of physical blocks. The garbage collection operation may be a technique for ensuring (or improving) usable capacity in the NVM 220 by erasing an existing block after copying valid data of the existing block to a new block.

The packet manager 215 may generate a packet according to a protocol of an interface, which consents to the host 100, and/or parse various types of information from the packet received from the host 100. In addition, the buffer memory 216 may temporarily store data to be written to the NVM 220 and/or data to be read from the NVM 220. Although the buffer memory 216 may be a component included in the storage controllers 210, the buffer memory 216 may be outside the storage controllers 210.

The ECC engine 217 may perform error detection and correction operations on read data read from the NVM 220. More specifically, the ECC engine 217 may generate parity bits for write data to be written to the NVM 220, and the generated parity bits may be stored in the NVM 220 together with write data. During the reading of data from the NVM 220, the ECC engine 217 may correct an error in the read data by using the parity bits read from the NVM 220 along with the read data, and output error-corrected read data.

The AES engine 218 may perform at least one of an encryption operation and/or a decryption operation on data input to the storage controllers 210 by using a symmetric-key algorithm.

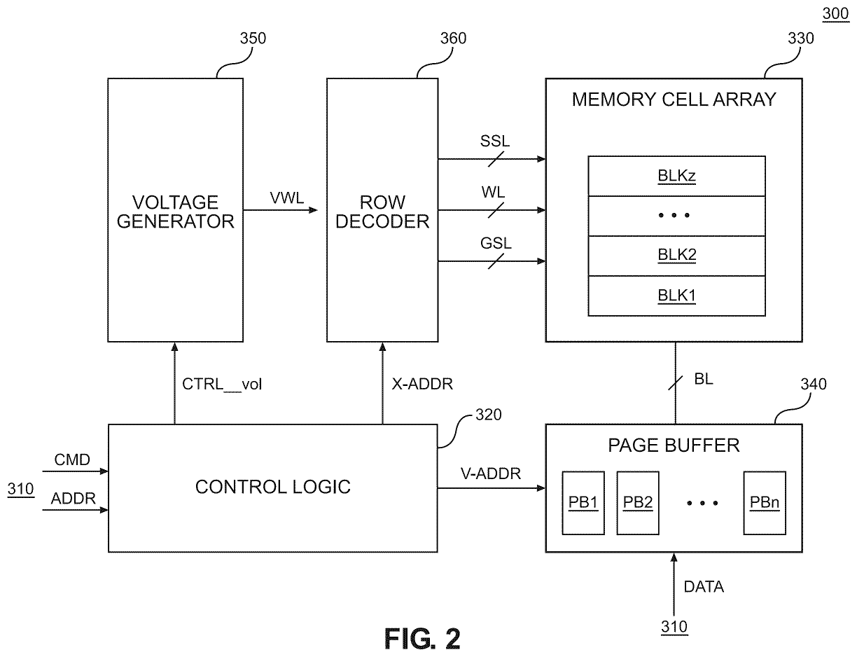

FIG. 2 illustrates a block diagram of a memory device 300, according to some example embodiments.

Referring to FIG. 2, the memory device 300 may include a control logic circuitry 320, a memory cell array 330, a page buffer 340, a voltage generator 350, and/or a row decoder 360. Although not shown in FIG. 2, the memory device 300 may further include a memory interface circuitry 310 shown in FIG. 2. In addition, the memory device 300 may further include a column logic, a pre-decoder, a temperature sensor, a command decoder, and/or an address decoder. According to some example embodiments, the memory device 300 may implement the NVM 220 discussed above in connection with FIG. 1.

The control logic circuitry 320 may control all various operations of the memory device 300. The control logic circuitry 320 may output various control signals in response to commands CMD and/or addresses ADDR from the memory interface circuitry 310. For example, the control logic circuitry 320 may output a voltage control signal CTRL_vol, a row address X-ADDR, and/or a column address Y-ADDR. According to some example embodiments, the memory interface circuitry 310 may receive the commands CMD and/or addresses ADDR from the memory interface 212 discussed above in connection with FIG. 1.

The memory cell array 330 may include a plurality of memory blocks BLK1 to BLKz (here, z is a positive integer), each of which may include a plurality of memory cells. The memory cell array 330 may be connected to the page buffer 340 through bit-lines BL and be connected to the row decoder 360 through word-lines WL, string selection lines SSL, and ground selection lines GSL.

In some example embodiments, the memory cell array 330 may include a 3D memory cell array, which includes a plurality of NAND strings. Each of the NAND strings may include memory cells respectively connected to word-lines vertically stacked on a substrate. The disclosures of U.S. Pat. Nos. 7,679,133; 8,553,466; 8,654,587; and 8,559,235; and US Pat. App. Pub. No. 2011/0233648 are hereby incorporated by reference. In some example embodiments, the memory cell array 330 may include a 2D memory cell array, which includes a plurality of NAND strings arranged in a row direction and a column direction.

The page buffer 340 may include a plurality of page buffers PB1 to PBn (here, n is an integer greater than or equal to 3), which may be respectively connected to the memory cells through a plurality of bit-lines BL. The page buffer 340 may select at least one of the bit-lines BL in response to the column address Y-ADDR. The page buffer 340 may operate as a write driver or a sense amplifier according to an operation mode. For example, during a program operation, the page buffer 340 may apply a bit-line voltage corresponding to data to be programmed, to the selected bit-line. During a read operation, the page buffer 340 may sense current or a voltage of the selected bit-line BL and sense data stored in the memory cell.

The voltage generator 350 may generate various kinds of voltages for program, read, and/or erase operations based on the voltage control signal CTRL_vol. For example, the voltage generator 350 may generate a program voltage, a read voltage, a program verification voltage, and/or an erase voltage as a word-line voltage VWL.

The row decoder 360 may select one of a plurality of word-lines WL and select one of a plurality of string selection lines SSL in response to the row address X-ADDR. For example, the row decoder 360 may apply the program voltage and the program verification voltage to the selected word-line WL during a program operation and apply the read voltage to the selected word-line WL during a read operation.

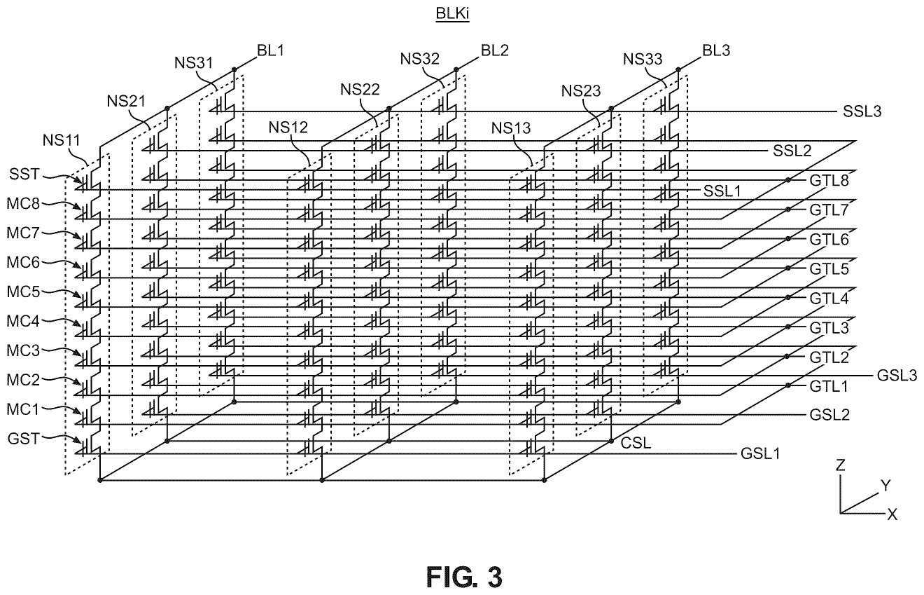

FIG. 3 illustrates a diagram of a 3D V-NAND structure, according to some example embodiments.

Referring to FIG. 3, a 3D V-NAND structure applicable to a UFS device is depicted. When a storage module (e.g., the memory cell array 330) of the UFS device (e.g., the storage device 200) is implemented as a 3D V-NAND flash memory, each of a plurality of memory blocks included in the storage module may be represented by an equivalent circuit shown in FIG. 3. According to some example embodiments, however, the storage device 200 may not be limited to the UFS device and may be a device conforming to a different standard (e.g., the eMMC standard) implemented using a corresponding 3D V-NAND structure.

A memory block BLKi shown in FIG. 3 may refer to a 3D memory block having a 3D structure formed on a substrate. For example, a plurality of memory NAND strings included in the memory block BLKi may be formed in a vertical direction (e.g., the z-direction as illustrated in FIG. 3) to the substrate.

Referring to FIG. 3, the memory block BLKi may include a plurality of memory NAND strings (e.g., NS11 to NS33), which are connected between bit-lines BL1, BL2, and BL3 and a common source line CSL. Each of the memory NAND strings NS11 to NS33 may include a string selection transistor SST, a plurality of memory cells (e.g., MC1, MC2, . . . , and MC8), and a ground selection transistor GST. Each of the memory NAND strings NS11 to NS33 is illustrated as including eight memory cells MC1, MC2, . . . , and MC8 in FIG. 3, without being limited thereto.

The string selection transistor SST may be connected to string selection lines SSL1, SSL2, and SSL3 corresponding thereto. Each of the memory cells MC1, MC2, . . . , and MC8 may be connected to a corresponding one of gate lines GTL1, GTL2, . . . , and GTL8. The gate lines GTL1, GTL2, . . . , and GTL8 may respectively correspond to word-lines, and some of the gate lines GTL1, GTL2, . . . , and GTL8 may correspond to dummy word-lines. The ground selection transistor GST may be connected to ground selection lines GSL1, GSL2, and GSL3 corresponding thereto. The string selection transistor SST may be connected to the bit-lines BL1, BL2, and BL3 corresponding thereto, and the ground selection transistor GST may be connected to the common source line CSL.

Word-lines (e.g., WL1) at the same level (or similar levels) may be connected in common, and the ground selection lines GSL1, GSL2, and GSL3 and the string selection lines SSL1, SSL2, and SSL3 may be separated from each other. FIG. 3 illustrates a case in which a memory block BLK is connected to eight gate lines GTL1, GTL2, . . . , and GTL8 and three bit-lines BL1, BL2, and BL3, without being limited thereto.

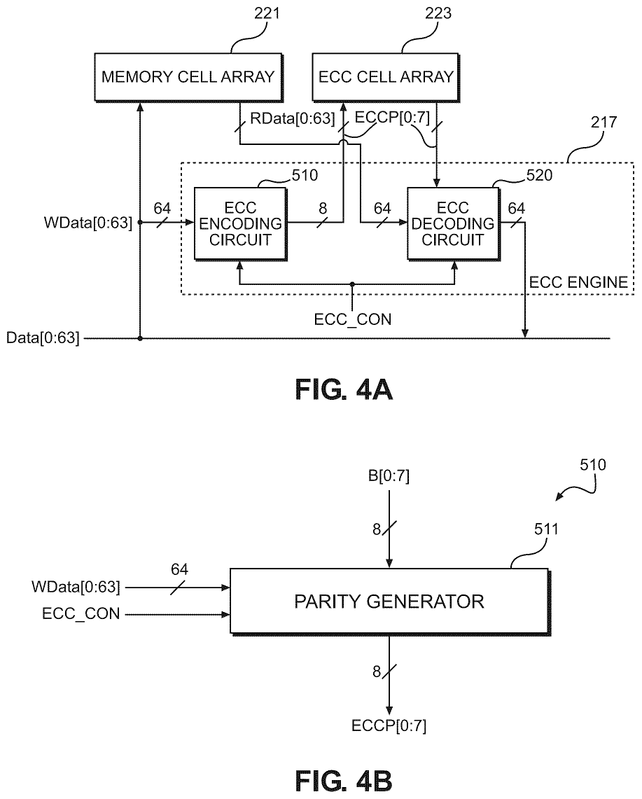

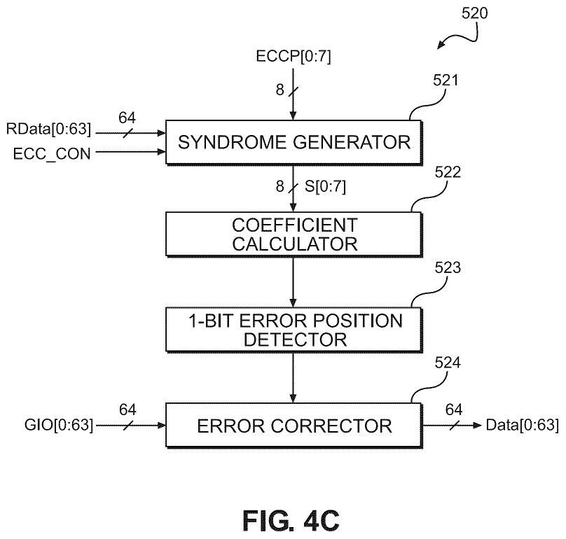

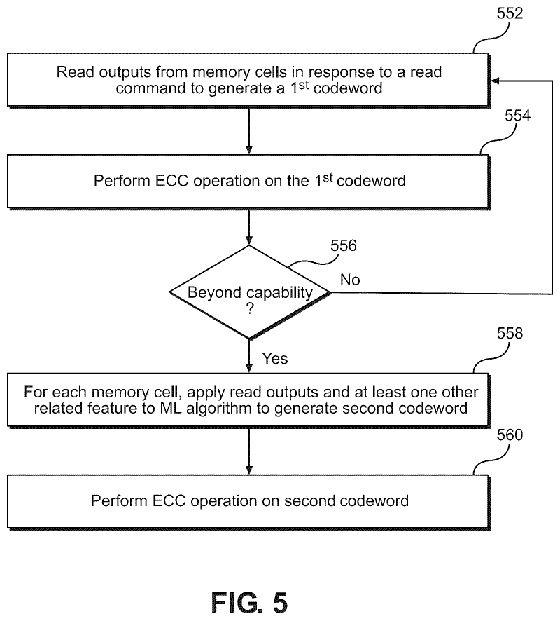

FIG. 4A illustrates a detailed diagram of the ECC engine 217, according to some example embodiments.

Referring to FIG. 4A, the ECC engine 217 may include an ECC encoding circuit 510 and/or an ECC decoding circuit 520. In response to an ECC control signal ECC_CON (e.g., from the CPU 213), the ECC encoding circuit 510 may generate parity bits ECCP[0:7] for write data WData[0:63] to be written to memory cells of a memory cell array 221. The parity bits ECCP[0:7] may be stored in an ECC cell array 223. According to some example embodiments, in response to the ECC control signal ECC_CON, the ECC encoding circuit 510 may generate parity bits ECCP[0:7] for write data WData[0:63] to be written to memory cells including a defective cell of the memory cell array 221. According to some example embodiments, one or both of the ECC cell array 223 and/or the memory cell array 221 may be included in the NVM 220. According to some example embodiments, the ECC cell array 223 and the memory cell array 221 may be included in different NVMs 220 included in the storage device 200.

In response to the ECC control signal ECC_CON, the ECC decoding circuit 520 may correct error bit data by using read data RData[0:63] read from the memory cells of the memory cell array 221 and parity bits ECCP[0:7] read from the ECC cell array 223, and output error-corrected data Data[0:63]. According to some example embodiments, in response to the ECC control signal ECC_CON, the ECC decoding circuit 520 may correct error bit data by using read data RData[0:63] read from memory cells including a defective cell of the memory cell array 221 and parity bits ECCP[0:7] read from the ECC cell array 223, and output error-corrected data Data[0:63].

FIG. 4B illustrates a diagram of the ECC encoding circuit 510, according to some example embodiments.

Referring to FIG. 4B, the ECC encoding circuit 510 may include a parity generator 511, which receives 64-bit write data WData[0:63] and basis bits B[0:7] in response to an ECC control signal ECC_CON, and generates parity bits ECCP[0:7] by using an XOR array operation. The basis bits B[0:7] may be bits for generating parity bits ECCP[0:7] for 64-bit write data WData[0:63], for example, b′00000000 bits. The basis bits B[0:7] may use other specific bits instead of b′00000000 bits.

FIG. 4C illustrates a diagram of the ECC decoding circuit 520, according to some example embodiments.

Referring to FIG. 4C, the ECC decoding circuit 520 may include a syndrome generator 521, a coefficient calculator 522, a 1-bit error position detector 523, and/or an error corrector 524. The syndrome generator 521 may receive 64-bit read data and an 8-bit parity bit ECCP[0:7] in response to an ECC control signal ECC_CON and generate syndrome data S[0:7] by using an XOR array operation. The coefficient calculator 522 may calculate a coefficient of an error position equation by using the syndrome data S[0:7]. The error position equation may be an equation that takes a reciprocal of an error bit as a root. The 1-bit error position detector 523 may calculate a position of a 1-bit error by using the calculated error position equation. The error corrector 524 may determine the position of the 1-bit error based on a detection result of the 1-bit error position detector 523. The error corrector 524 may correct an error by inverting a logic value of a bit of which an error occurs, from among 64-bit read data RData[0:63], based on determined 1-bit error position information, and output error-corrected 64-bit data Data[0:63].

Each of the memory cells in the memory cell array 221 may be configured to store multiple bits of data (e.g., may be a multi-level memory cell). In order to implement such multi-level memory cells, a threshold voltage range of each memory cell is divided into a specific quantity of voltage states, each of the voltage states representing a corresponding data value stored in the memory cell. For example, if each memory cell is capable of storing 4 bits of data (e.g., 0000, 0001, . . . 1111), then there may be 16 different threshold voltage levels to represent these 16 different states, such as an erase state and 15 other program states. Accordingly, when a cell voltage of a memory cell being read is less than a first (e.g., lowest) one of these threshold voltage levels, the memory cell may be considered to be in an erase state, and when the cell voltage is between the first threshold voltage level and a second (e.g., a next highest) threshold voltage level, the memory cell would be considered to be in a first program state (e.g., 0001).

However, as the quantity of voltage states the memory cells are configured to implement increases, a dynamic voltage range of each voltage state decreases, rendering the memory cells more susceptible to noise (e.g., Inter-Symbol-Interference (ISI)). Sources of such noise may include, for example, inter-wordline interference, intra-wordline interference, retention noise depending on neighbor memory cells, and different wordlines behaving differently due to process, voltage, or temperature changes. When such noise changes a cell voltage to such an extent that it crosses one of the threshold voltage levels, or drifts sufficiently close to one of the threshold voltage levels that it becomes difficult to distinguish on which side of the threshold voltage level the cell voltage falls, an error may occur in the read data.

Systems for implementing ECCs may be configured to correct a certain number of bit errors (e.g., 1 bit or 2 bits). However, when this number of errors has been exceeded conventional devices and methods are unable to correct the errors and recover the original data. In such scenarios, the conventional devices and methods merely respond to a corresponding read command with an indication that the original data has been corrupted and is unrecoverable. Accordingly, the conventional devices and methods suffer from an excessive amount of data loss (e.g., an excessive Bit Error Rate (BER)). Also, while it may be possible to mitigate some of this data loss by allocating additional resources (e.g., additional memory for data mirroring, additional processing, power resources and delay to implement more complex ECC schemes and/or increased parity bit size), this results in excessive resource consumption (e.g., memory, processor, power, delay, etc.) which is particularly disadvantageous for ECC systems implemented on mobile devices (devices having limited resources). However, according to example embodiments, improved devices and methods are provided for retrieving target data using ECCs that avoid or mitigate these disadvantages.

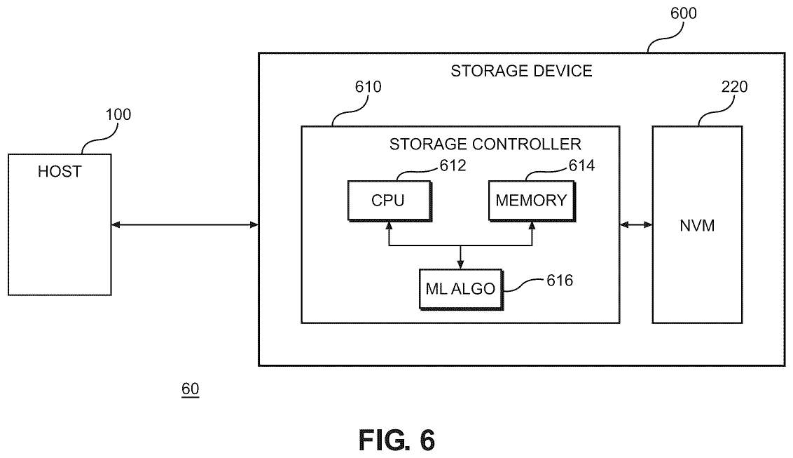

FIG. 5 illustrates a method of performing an error correction operation, according to some example embodiments.

Referring to FIG. 5, at operation 552, recorded data may be read from one or more memory cells in response to a read command to obtain a first codeword. For example, the storage controller 210 may read data from memory cells of the NVM 220 in response to a command from the host controller 110. The read data may be referred to as the first codeword. According to some example embodiments, the first codeword may include data read from multiple memory cells (e.g., all of the memory cells in a target word-line, etc.), but some example embodiments are not limited thereto and only a single memory cell (e.g., a target memory cell) may be read to form the first codeword. In an illustrative example with reference to FIG. 3, the target memory cell may be the memory cell MC4 and the target word-line may correspond to (e.g., may be) all of memory cells connected to the gate line GTL4. According to some example embodiments, the target memory cell voltage (or target word-line voltages) may be detected only once in operation 552 or multiple times (e.g., by repeating operation 552). In scenarios in which the target memory cell voltage (or the voltage of each memory cell in the target word-line) is detected multiple times, the target memory cell (or memory cell in the target word-line) voltage may be determined as, for example, an average of the multiple detected target memory cell voltages.

At operation 554, the storage controller 210 may perform an ECC operation on the first codeword. For example, the CPU 213 of the storage controller 210 may provide the read data to the ECC engine 217. The ECC decoding circuit 520 may receive the codeword (e.g., 64-bit read data) and attempt to correct any errors within the codeword.

At operation 556, the storage controller 210 may determine whether the ECC operation was successful. For example, the storage controller 210 may determine whether the ECC decoding circuit 520 identified a quantity of bit errors greater than or equal to a threshold quantity of bit errors that the ECC decoding circuit 520 is configured to correct. Alternatively or additionally, the storage controller 210 may determine whether the ECC decoding circuit 520 corrected the detected bit errors but that the resulting corrected data was still corrupted (e.g., erroneous). In response to determining that the ECC operation was successful (Yes in operation 556), the method may return to operation 552 to read another codeword.

In some other examples, in response to determining that the ECC operation was not successful (No in operation 556), the recorded data read from the one or more memory cells (e.g., the first codeword) may be input into a Machine Learning (ML) algorithm along with at least one other feature in operation 558. According to some example embodiments, in scenarios in which the first codewords include the voltages of memory cells in the target word-line, the voltage of each memory cell in the target word-line may be separately input into the ML algorithm along with the at least one other feature. As will be discussed further below, the ML algorithm may be trained to output a second codeword (or data representative of the second codeword) based on the input of such data. According to some example embodiments, in scenarios in which the first codewords include the voltages of memory cells in the target word-line, the second codeword may include a combination (e.g., concatenation) of outputs respective corresponding to the memory cell voltages of the target word-line separately input into the ML algorithm. At operation 560, the storage controller 210 may perform another ECC operation on the second codeword (e.g., on data based on the output of the ML algorithm). For example, the CPU 213 of the storage controller 210 may provide the second codeword to the ECC engine 217 and the ECC decoding circuit 520 may correct any errors within the second codeword to accurately recover the data read from the one or more memory cells. According to some example embodiments, operation 556, operation 558 and/or operation 560 may be performed by any among the storage controller 210, the CPU 213, the ECC engine 217 or the ECC decoding circuit 520, but some example embodiments are not limited thereto.

While the above-described operations illustrated in FIG. 5 indicate that the second codeword is obtained from the ML algorithm in response to a determination that an ECC operation performed on the first codeword was unsuccessful, some example embodiments are not limited thereto. According to some example embodiments, the second codeword may be obtained from the ML algorithm (e.g., in every instance, in circumstances conditioned on a characteristic(s) of the one or more memory cells from which the first codeword is read, etc.) without performing operation 554 or operation 556. According to some example embodiments, the second codeword may be obtained from the ML algorithm (e.g., operation 558 may be performed) in response to determining that a value of the first codeword falls within a weak decision range between two voltage threshold values, as discussed further below, without performing operation 554 or operation 556. According to some example embodiments, in a scenario in which the ECC operation performed in operation 560 is unsuccessful, the storage controller 210 may output a message to the host controller 110 indicating that the original data has been corrupted and is unrecoverable.

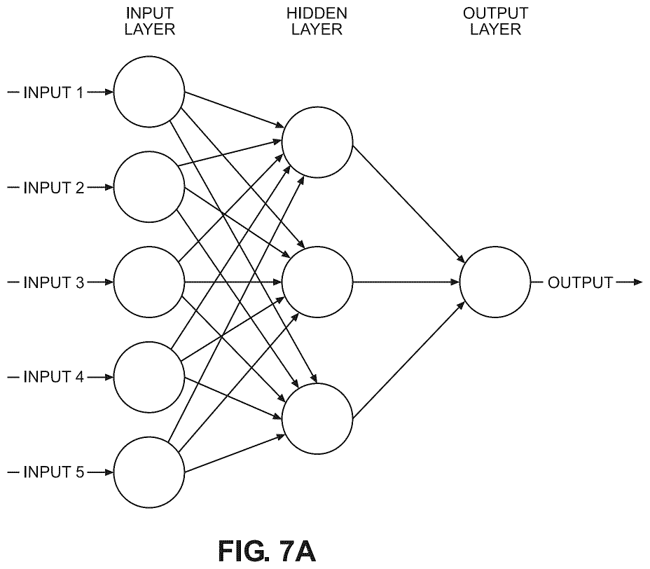

FIG. 6 illustrates a block diagram of a host storage system implementing an ML algorithm, according to some example embodiments.

Referring to FIG. 6, a host storage system 60 may include the host 100 and/or a storage device 600. Further, the storage device 200 may include a storage controller 610 and/or the Non-Volatile Memory (NVM) 220. According to some example embodiments, the host 100 and/or the NVM 220 may be the same as or similar to those discussed in connection with FIG. 1 and will not be described in further detail to limit redundancy.

The storage controller 610 may include a CPU 612, a memory 614 and/or an ML algorithm 616. The CPU 612 may control overall operation of the storage controller 610 (and/or the storage 600). The CPU 612 may store and/or retrieve data to and/or from the memory 614 (e.g., programming instructions for execution by the CPU 612, operational data generated by the CPU 612, etc.). The CPU 612 may communicate with, and/or control, the ML algorithm 616 and/or the NVM 220. According to some example embodiments, the CPU 612 may be configured to implement the host interface 211, the memory interface 212, the CPU 213, the FTL 214, the packet manager 215, the ECC engine 217, and/or the AES engine 218 discussed in connection with FIG. 1. Although FIG. 6 illustrates the ML algorithm 616 as being a separate component from the CPU 612, some example embodiments are not limited thereto and the ML algorithm 616 may be implemented by the CPU 612.

According to some example embodiments, operations described herein as being performed by the host storage system 10, the host 100, the storage device 200, the storage controller 210, the host controller 110, the host interface 211, the memory interface 212, the CPU 213, the FTL 214, the packet manager 215, the ECC engine 217, the AES engine 218, the memory device 300, memory interface circuitry 310, the control logic circuitry 320, the page buffer 340, the voltage generator 350, the row decoder 360, the ECC encoding circuit 510, the ECC decoding circuit 520, the parity generator 511, the syndrome generator 521, the coefficient calculator 522, the 1-bit error position detector 523, the error corrector 524, the host storage system 60, the storage device 600, the storage controller 610, and/or the CPU 612 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

The memory 614 may be a tangible, non-transitory computer-readable medium, such as a Random Access Memory (RAM), a flash memory, a Read Only Memory (ROM), an Electrically Programmable ROM (EPROM), an Electrically Erasable Programmable ROM (EEPROM), registers, a hard disk, a removable disk, a Compact Disk (CD) ROM, any combination thereof, or any other form of storage medium known in the art. The memory 614 may store data and/or instructions for retrieval by, for example, the CPU 612.

The ML algorithm 616 may be trained to generate a second codeword in response to a first codeword and at least one other feature being input to the ML algorithm 616 (e.g., by the CPU 612). The ML algorithm 616 may also be referred to herein as an equalizer. The ML algorithm 616 may be trained to recognize correlations between the first codeword and the at least one other feature, and a correct (or improved) cell voltage.

In some example embodiments, the processing circuitry may perform some operations (e.g., the operations described herein as being performed by the ML algorithm 616) by artificial intelligence and/or machine learning. As an example, the processing circuitry may implement an artificial neural network (e.g., the ML algorithm 616) that is trained on a set of training data by, for example, a supervised, unsupervised, and/or reinforcement learning model, and wherein the processing circuitry may process a feature vector to provide output based upon the training. Such artificial neural networks may utilize a variety of artificial neural network organizational and processing models, such as convolutional neural networks (CNN), recurrent neural networks (RNN) optionally including long short-term memory (LSTM) units and/or gated recurrent units (GRU), stacking-based deep neural networks (S-DNN), state-space dynamic neural networks (S-SDNN), deconvolution networks, deep belief networks (DBN), and/or restricted Boltzmann machines (RBM). Alternatively or additionally, the processing circuitry may include other forms of artificial intelligence and/or machine learning, such as, for example, linear and/or logistic regression, statistical clustering, Bayesian classification, decision trees, dimensionality reduction such as principal component analysis, and expert systems; and/or combinations thereof, including ensembles such as random forests.

Herein, the machine learning model (e.g., the ML algorithm 616) may have any structure that is trainable, e.g., with training data. For example, the machine learning model may include an artificial neural network, a decision tree, a support vector machine, a Bayesian network, a genetic algorithm, and/or the like. The machine learning model will now be described by mainly referring to an artificial neural network, but some example embodiments are not limited thereto. Non-limiting examples of the artificial neural network may include a convolution neural network (CNN), a region based convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzmann machine (RBM), a fully convolutional network, a long short-term memory (LSTM) network, a classification network, and/or the like.

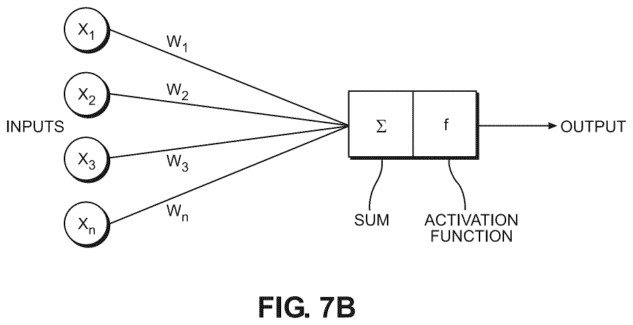

According to some example embodiments, the ML algorithm 616 may be implemented using a trained artificial neural network (ANN). FIGS. 7A-7B illustrate graphical representations of example recurrent neural networks for implementing the ML algorithm 616, according to some example embodiments.

Referring to FIG. 7A, machine learning is a method used to devise complex models and algorithms that lend themselves to prediction (for example, one or more LLRs reflecting a correct (e.g., pre-retention) cell voltage). Models generated using machine learning, such as those described above, may produce reliable, repeatable decisions and results, and uncover hidden insights through learning from historical relationships and trends in within data.

The use of a recurrent neural-network-based model, and training of the model using machine learning as described herein, may enable direct predictions of dependent variables without casting relationships between the variables into mathematical form. The neural network model includes a large number of virtual neurons operating in parallel and arranged in layers. The first layer is the input layer and receives raw input data. Each successive layer modifies outputs from a preceding layer and sends them to a next layer. The last layer is the output layer and produces output of the system.

FIG. 7A shows a fully connected neural network, where each neuron in a given layer is connected to each neuron in a next layer, according to some example embodiments. In the input layer, each input node is associated with a numerical value, which may be any real number. In each layer, each connection that departs from an input node has a weight associated with it, which may also be any real number (see FIG. 7B). In the input layer, the number of neurons equals number of features (columns) in a dataset. The output layer may have multiple continuous outputs.

The layers between the input and output layers are hidden layers. The number of hidden layers may be one or more (one hidden layer may be sufficient for most applications). A neural network with no hidden layers may represent linear separable functions or decisions. A neural network with one hidden layer may perform continuous mapping from one finite space to another. A neural network with two hidden layers may approximate any smooth mapping to any accuracy.

The number of neurons may be optimized (or adjusted). At the beginning of training, a network configuration is more likely to have excess nodes. Some of the nodes may be removed from the network during training that would not noticeably affect network performance. For example, nodes with weights approaching zero after training may be removed (this process is called pruning). The number of neurons may cause under-fitting (inability to adequately capture signals in dataset) or over-fitting (insufficient information to train all neurons; network performs well on training dataset but not on test dataset).

Various methods and criteria may be used to measure performance of a neural network model. For example, root mean squared error (RMSE) measures the average distance between observed values and model predictions. Coefficient of Determination (R²) measures correlation (not accuracy) between observed and predicted outcomes. This method may not be reliable if the data has a large variance. Other performance measures include irreducible noise, model bias, and model variance. A high model bias for a model indicates that the model is not able to capture true relationship between predictors and the outcome. Model variance may indicate whether a model is stable (a slight perturbation in the data will significantly change the model fit).

Referring to FIG. 6, the detected voltage of a memory cell may drift from the voltage with which the memory cell was programmed. For example, a given memory cell may be programmed by applying a sequence of voltage pulses to the memory cell to bring a voltage of the memory cell to within a desired voltage window corresponding to a desired voltage threshold value. Upon completion of the programming, electrical charges concentrate near a center of the memory cell. However, over time these charges leak out in different directions due to various retention effects. For example, the voltage of the memory cell may be determined based on an amount of charge trapped in a silicon-nitride layer of the memory cell. The retention effects may result in the charges leaking from (e.g., through) the silicon-nitride layer.

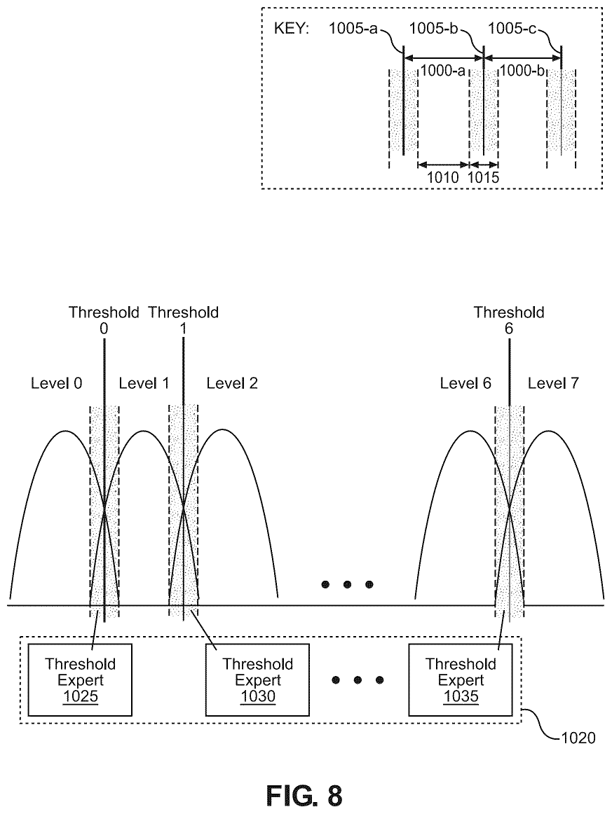

According to some example embodiments, the at least one other feature (may also be referred to herein as retention feature(s)) input to the ML algorithm 616 may reflect a characteristic(s) that correlates the detected memory cell voltage to a correct (or improved) cell voltage (e.g., a voltage of the cell before the retention effects). For example, the characteristic(s) may be representative of the charge leakage from a memory cell due to the retention effects. The ML algorithm 616 may be trained to correlate the at least one retention feature with a correct (or improved) cell voltage (e.g., an originally programmed voltage or a pre-retention voltage). According to some example embodiments, the at least one retention feature may include programming pulse read voltages, a post-erasure voltage, and/or neighbor voltages, but some example embodiments are not limited thereto. For example, the at least one retention feature may also include one or more among a hard decision threshold (e.g., for a target word-line and/or a target memory cell), a soft decision threshold (e.g., for a target word-line and/or a target memory cell), and/or an index (e.g., of a target word-line and/or target memory cell). According to some example embodiments, the hard decision threshold and/or the soft decision threshold may vary among word-lines (and/or memory cells) of the NVM 220. According to some example embodiments, the hard decision threshold may correspond to the hard decision threshold 1005, and/or the soft decision threshold may correspond to the weak decision range 1015, discussed below in connection with FIG. 8.

As discussed herein, a target word-line may be a word-line including a target memory cell, and/or neighboring word-lines may be word-lines immediately adjacent to (or otherwise, nearby) the target word-line. According to some example embodiments, the at least one retention feature (e.g., the programming pulse read voltages, the post-erasure voltage, and/or the neighbor voltages) may be generated and/or detected by, for example, the CPU 612 and/or the control logic 320.

The response of a memory cell to a programming pulse depends on various parameters, such as a charge distribution in the silicon-nitride layer of the memory cell, the width of an oxide (tunneling) layer of the memory cell, a number of defects in the oxide layer, etc. The charge distribution in the silicon-nitride layer after the above-described charge leakage (e.g., post-retention) is related to charge migration after programming. Also, the width of the oxide layer corresponds to a rate of the charge leakage outside of the silicon-nitride layer. Memory cells having the same post-retention voltage (or similar post-retention voltages) will respond to a programming pulse (e.g., the same programming pulse or similar programming pulses) differently according to the pre-retention voltages of the memory cells (e.g., the voltages with which the memory cells were originally programmed). Accordingly, voltages read from a memory cell after programming pulses are applied post-retention may correlate to the correct (e.g., pre-retention) cell voltage. As such, the at least one retention feature may include programming pulse read voltages of the memory cell.

For example, according to some example embodiments, the programming pulse read voltages of a target word-line may be generated and/or collected by applying a sequence of programming pulses to all memory cells in the target word-line and the voltage of the target word-line (e.g., the voltages of each of the memory cells on the target word-line) may be read between at least some of the programming pulses. According to some example embodiments, the sequence of programming pulses may include a sequence of twenty pulses of increasing magnitude, but some example embodiments are not limited thereto and the sequence may include a different quantity of programming pulses. According to some example embodiments, the target word-line may be read after the 9^{th}, 15^{th}, 17^{th}, and 19^{th} programming pulses, but this is merely an example and some example embodiments are not limited thereto. According to some example embodiments, the programming pulse read voltages of the target word-line may be generated as containing the voltages of the target word-line detected (e.g., read).

While the programming pulse read voltages may be described herein as corresponding to the voltages of an entire word-line, this is merely an example and some example embodiments are not limited thereto. According to some example embodiments, the programming pulse read voltages may be generated and/or collected with respect to only one target memory cell, such as by applying the sequence of programming pulses to the target memory cell and reading the voltage the target memory cell between at least some of the programming pulses.

According to some example embodiments, each of the programming pulse read voltages may be read (e.g., detected) only once or multiple times. In scenarios in which each of the programming pulse read voltages is read multiple times, each programming pulse read voltage (e.g., a single voltage read after a given programming pulse) may be determined as, for example, an average of the multiple detected programming pulse read voltages (e.g., of the multiple voltages read after the given programming pulse). According to some example embodiments, the programming pulse read voltages may be stored, for example, in the memory 614.

According to some example embodiments, prior to applying the programming pulses to the target word-line (or target memory cell), the data written to the target word-line (or to a target memory block BLK containing the target memory cell) may be backed up (e.g., copied) elsewhere (e.g., to another word-line or memory block BLK in the NVM 220). By backing up the data, data loss or corruption due to the applied programming pulses may be prevented or reduced. Additionally or alternatively, the data stored on the target word-line may be rewritten to an available word-line after being decoded. Additionally or alternatively, according to some example embodiments, the programming pulses may be configured to minimize or reduce the adverse effects on the remaining data on the memory block BLK.

When a memory cell is erased, holes are injected into the silicon-nitride layer of the memory cell to recombine with electrons, shifting the voltage of the memory cell to a negative erase level. The memory cell erasure may be performed by applying a strong negative voltage between the memory cell's gate and a substrate, effectively changing the memory cell's area from being electron enriched to hole enriched. Electron residues at an inter-cell spacing provide correlations between a memory cell's retention and the memory cell's voltage after the erase operation. For example, the voltage of a memory cell after the erase operation may vary with respect to that of other memory cells having the same post-retention voltage (or similar post-retention voltages) by an amount corresponding to the pre-retention voltage of the memory cells (e.g., the voltage with which the memory cell was originally programmed).

In an illustrative example, memory cells may be split into different bins based on their post-retention voltages such that subsets of the memory cells having post-retention voltages within a threshold range of a given voltage threshold value may be split into the same bin (or similar bins). With respect to each of the different bins, the subset of memory cells in the bin may be separated according to the pre-retention voltages of these memory cells. The mean voltage of these memory cells after performance of the erase operation correlates to the pre-retention voltages of these memory cells. Accordingly, the post-erasure voltage of a target memory cell may correlate to the correct (or improved) cell voltage of the target memory cell. As such, the at least one retention feature may include the post-erasure voltage of the target memory cell.

According to some example embodiments, the post-erasure voltage of a target word-line (e.g., the voltages of all of the memory cells on the target word-line) may be generated and/or collected by performing an erasure operation on the target word-line, however this is merely an example and some example embodiments are not limited thereto. According to some example embodiments, the post-erasure voltage may be generated and/or collected with respect to only one target memory cell, such as by performing the erasure operation on the target memory cell and reading the voltage the target memory cell after performing the erasure operation. According to some example embodiments, the erasure operation as described herein may refer to a full erasure of the target word-line (or target memory cell) or only a partial erasure of the target word-line (or target memory cell). According to some example embodiments, each of the post-erasure voltages may be read (e.g., detected) only once or multiple times. In scenarios in which each post-erasure voltage is read multiple times, the post-erasure voltage may be determined as, for example, an average of the multiple detected post-erasure voltages. According to some example embodiments, the post-erasure voltage may be stored, for example, in the memory 614.

According to some example embodiments, erasure operations performed on the NVM 220 may act on all memory cells within a given memory block BLK. In such scenarios, the erasure operation may include erasing all of the memory cells within the target memory block BLK. After completion of the erasure operation, the voltages of the target word-line (and/or the voltage of the target memory cell) may be read. According to some example embodiments, prior to performing the erasure operation, the data written to target memory block BLK (including the data written to the target word-line and/or the target memory cell) may be backed up (e.g., copied) elsewhere (e.g., to another memory block BLK in the NVM 220). By backing up the data, data loss or corruption due to the erasure operation may be prevented or reduced. According to some example embodiments, the post-erasure voltage may be generated as containing the voltages of the target word-line (and/or the voltage of the target memory cell) detected (e.g., read).

The amount of charges that leak from a target memory cell depends, among other factors, on the difference in voltages between the target and neighboring cells. Accordingly, voltages detected (e.g., read) in neighboring memory cells may correlate to the correct (or improved) cell voltage of the target memory cell. As such, the at least one retention feature may include neighbor voltages. Neighboring memory cells may include memory cells adjacent to the target memory cell with respect to either a word-line or a bit-line. The neighboring memory cells will be discussed mainly herein as corresponding to those adjacent to the target memory cell with respect to the word-line, but this is merely an example and some example embodiments are not limited thereto. For example, in some example embodiments, the voltages of the neighboring word-lines (e.g., the neighbor voltages) may include, additionally or alternatively, voltages of neighboring bit-lines.

According to some example embodiments, the voltage(s) of one or more neighboring word-lines (e.g., the voltages of all of the memory cells included on the one or more neighboring word-lines) may be detected (e.g., read). For example, neighboring word-lines may be word-lines immediately adjacent (or otherwise, nearby) the target word-line. In the illustrative example with reference to FIG. 3, the target word-line may be the gate line GTL 4, and the neighboring word-lines may be the gate line GTL 3 and the gate line GTL 5 adjacent to the target word-line GTL 4. As such, the neighboring word-line voltage(s) may correspond to (e.g., may be) the voltages of the memory cells connected to the gate line GTL 3 and/or the gate line GTL 5. According to some example embodiments, the voltages of both neighboring word-lines may be detected, but some example embodiments are not limited thereto and the voltage of only one of the neighboring word-lines may be detected. According to some example embodiments, each neighboring word-line voltage may be detected only once or multiple times. In scenarios in which each neighboring word-line voltage is detected multiple times, each neighboring word-line voltage (e.g., a single voltage read with respect to a given neighboring word-line) may be determined as, for example, an average of the multiple detected word-line voltages for that neighboring word-line. According to some example embodiments, the neighboring word-line voltages may be stored, for example, in the memory 614.

While the above discussion of the neighboring word-line voltages describes detecting the voltages of entire word-lines, this is merely an example and some example embodiments are not limited thereto. In some example embodiments, the neighboring word-line voltages may include only the voltages of one or more of word-line (WL) neighboring memory cells. The WL neighboring memory cells may be memory cells immediately adjacent (or otherwise, nearby) the target memory cell with respect to the neighboring word-lines. In the illustrative example with reference to FIG. 3, and the WL neighboring memory cells may be memory cell MC3 and memory cell MC5 adjacent to the target memory cell MC4. As such, the WL neighboring memory cell voltage(s) may correspond to (e.g., may be) the voltages of the memory cell MC3 and/or the memory cell MC5. The target memory cell and the WL neighboring memory cells may be included the same memory string (or similar memory strings). For example, the target memory cell and the WL neighboring memory cells may be included in the memory string NS22. According to some example embodiments, the voltages of both WL neighboring memory cells may be detected, but some example embodiments are not limited thereto and the voltage of only one of the WL neighboring memory cells may be detected. According to some example embodiments, each WL neighboring memory cell voltage may be detected only once or multiple times. In scenarios in which each WL neighboring memory cell voltage is detected multiple times, each WL neighboring memory cell voltage (e.g., a single voltage read with respect to a given WL neighboring memory cell) may be determined as, for example, an average of the multiple detected memory cell voltages for that WL neighboring memory cell. According to some example embodiments, the WL neighboring memory cell voltages may be stored, for example, in the memory 614.

As noted above, in some example embodiments, the voltages of the neighboring word-lines may include, additionally or alternatively, voltages of neighboring bit-lines. In such scenarios, the voltage(s) of one or more neighboring bit-lines (e.g., the voltages of all of the memory cells included on the one or more neighboring bit-lines) may be detected (e.g., read). For example, neighboring bit-lines may be word-lines immediately adjacent (or otherwise, nearby) a target bit-line. According to some example embodiments, the target bit-line may be a bit-line of the target memory cell. In an illustrative example with reference to FIG. 3, the target bit-line may be the bit-line BL2, and the neighboring bit-lines may be the bit-line BL1 and the bit-line BL3 adjacent to the target bit-line BL2. As such, the neighboring bit-line voltage(s) may correspond to (e.g., may be) the voltages of the memory cells on the bit-line BL1 and/or the bit-line BL3. According to some example embodiments, the voltages of both neighboring bit-lines may be detected, but some example embodiments are not limited thereto and the voltage of only one of the neighboring bit-lines may be detected. According to some example embodiments, each neighboring bit-line voltage may be detected only once or multiple times. In scenarios in which each neighboring bit-line voltage is detected multiple times, each neighboring bit-line voltage (e.g., a single voltage read with respect to a given neighboring bit-line) may be determined as, for example, an average of the multiple detected bit-line voltages for that neighboring bit-line. According to some example embodiments, the neighboring bit-line voltages may be stored, for example, in the memory 614.

While the above discussion of the neighboring bit-line voltages describes detecting the voltages of entire bit-lines, this is merely an example and some example embodiments are not limited thereto. In some example embodiments, the neighboring bit-line voltages may include only the voltages of one or more of bit-line (BL) neighboring memory cells. The BL neighboring memory cells may be memory cells immediately adjacent (or otherwise, nearby) the target memory cell with respect to the neighboring bit-lines. In the illustrative example with reference to FIG. 3, and the BL neighboring memory cells may be memory cells MC4 on memory strings NS21 and NS23 adjacent to the target memory cell MC4 on memory string NS22. As such, the BL neighboring memory cell voltage(s) may correspond to (e.g., may be) the voltages of the memory cells MC4 on memory strings NS21 and NS23. According to some example embodiments, the voltages of both BL neighboring memory cells may be detected, but some example embodiments are not limited thereto and the voltage of only one of the BL neighboring memory cells may be detected. According to some example embodiments, each BL neighboring memory cell voltage may be detected only once or multiple times. In scenarios in which each BL neighboring memory cell voltage is detected multiple times, each BL neighboring memory cell voltage (e.g., a single voltage read with respect to a given BL neighboring memory cell) may be determined as, for example, an average of the multiple detected memory cell voltages for that BL neighboring memory cell. According to some example embodiments, the BL neighboring memory cell voltages may be stored, for example, in the memory 614.

According to some example embodiments, the ML algorithm 616 may be trained to output one or more Log-Likelihood Ratios (LLRs) in response to input of the first codeword and the at least one other feature. Each LLR may reflect a probability of a corresponding bit being a logical ‘0’ or ‘1’. The ECC decoding circuit 520 may be configured to determine the correct (e.g., pre-retention) cell voltage(s) based on the one or more LLRs output by the ML algorithm 616. According to some example embodiments, the ECC decoding circuit 520 may be configured to input three soft-decision (SD) bits. In such a scenario, the CPU 612 may convert an LLR into three SD bits using, for example, an LLR to SD bit table stored in the memory 614. The LLR to SD bit table may store each potential combination of SD bits in association with a corresponding LLR. Accordingly, the CPU 612 may convert an LLR output by the ML algorithm into three SB bits by determining an LLR stored in the table that has a value closest to the output LLR, and determining the associated SD bits to be the SB bits representing the converted LLR.

According to some example embodiments, the ML algorithm 616 may be implemented using a single artificial neural network (ANN) trained to output a separate LLR for each of a voltage threshold level of a memory cell. For example, in a scenario in which each memory cell of the NVM 220 is configured to be set (e.g., programmed or erased) to one of 16 possible states, the ML algorithm 616 may be trained to output 16 separate LLRs for each memory cell to be read. In a scenario in which the first codeword contains the read voltage of a single memory cell, the ML algorithm 616 may be trained to output 16 separate LLRs for that memory cell (e.g., via 16 parallel output nodes). According to some example embodiments, the CPU 612 may compute a single LLR for the memory cell based on the 16 separate LLRs output by the ML algorithm 616. For example, the CPU 612 may determine the two highest LLRs (likely adjacent to one another) and compute the single LLR based on the two highest LLRs (e.g., based on a difference between the two highest LLRs). However, this implementation of the ML algorithm using a single ANN is merely an example and some example embodiments are not limited thereto.

According to some example embodiments, the ML algorithm may be implemented using a plurality of ANNs including a different ANN for each weak decision voltage range between the voltage threshold levels of a memory cell. For example, each respective ANN among the plurality of ANNs may be trained to distinguish between a different pair of adjacent voltage threshold levels of a target memory cell. As such, each respective ANN may be referred to herein as a threshold expert with respect to the pair of adjacent voltage threshold levels between which the respective ANN is trained to distinguish.

According to some example embodiments, the ML algorithm 616 implemented using the plurality of ANNs may include multiple shallow machine learning models, where each machine learning model is trained to specifically solve a classification task (e.g., a binary classification task) corresponding to a weak decision range between two possible read information values for a given memory cell read operation. Accordingly, during inference, each read sample with a read value within a weak decision range may be passed through a corresponding shallow machine learning model (e.g., a corresponding threshold expert) that is associated with (e.g., trained for) a particular weak decision range.

The plurality of threshold expert shallow machine learning models may thus output improved soft symbols estimation for their respective weak decision ranges (e.g., due to training of each threshold expert to handle classification tasks associated with specific weak decision ranges). The improved soft symbol estimations may be used to generate improved codewords for subsequent ECC operations (e.g., which may improve EEC operation efficiency). Utilization of multiple shallow machine learning models, each trained to solve a specific binary classification task associated with different weak decision ranges, may also result in a set of machine learning models that may be operated with lower memory usage (e.g., less memory usage than ECC) and lower latency. Further, such equalization models may be implemented in firmware, such that the equalizer models may be used by various NAND flash memory architectures.

FIG. 8 illustrates graphical representations of example weak decision voltage ranges and hard decision voltage ranges, according to some example embodiments.

Referring to FIG. 8, example voltage threshold levels are shown for memory cells configured to represent eight voltage levels (e.g., three bits of data). However, this is merely an example and some example embodiments are not limited thereto.

In the example of FIG. 8, eight levels are shown (e.g., ‘Level 0,’ ‘Level 1,’ . . . ‘Level 7’) that may each be represented by three bits (e.g., ‘000’=‘Level 0’; ‘001’=‘Level 1;’ . . . ‘111’=‘Level 7’). Hard decision (HD) thresholds 1005 (e.g., HD threshold 1005-a, HD threshold 1005-b, HD threshold 1005-c, etc.) may be defined between each pair of neighboring levels. Moreover, within a dynamic range spanning from ‘Level 0’ to ‘Level 7,’ strong decision ranges 1010 and weak decision ranges 1015 may be defined. Strong decision ranges 1010 may refer to ranges (e.g., voltage ranges) where the voltage threshold level of a memory cell is readily determined (e.g., by a voltage detector). Weak decision ranges 1015 may include ranges surrounding a HD threshold 1005, where the voltage threshold level of a memory cell is not readily determined (e.g., by a voltage detector). For instance, a weak decision range 1015 may include values (e.g., voltage values) closely preceding and closely subsequent to HD thresholds 1005.

Generally, voltage threshold levels may be distinguishable based on HD thresholds 1005, and voltage threshold levels may include strong decision ranges 1010 and portions of weak decision ranges 1015. Read information (e.g., detected voltages) within a strong decision range 1010 may be readily classified as a corresponding voltage threshold level (e.g., by a voltage detector without the use of a threshold expert). Read information (e.g., detected voltages) within a weak decision range 1015 may be passed to a selection component, where the selection component may select a threshold network to classify the read information as one of the two neighboring voltage threshold levels. In the example of FIG. 8, a HD threshold 1005-b may reside between a level 1000-a and a level 1000-b. A weak decision range 1015 may include the range between the level 1000-a and a level 1000-b with respect to which further analysis on the read information may be performed via a corresponding threshold network from a plurality of threshold networks 1020 (e.g., the plurality of ANNs). According to some example embodiments, the plurality of threshold networks 1020 may include a first threshold expert 1025, a second threshold expert 1030, . . . and an n^{th} threshold expert 1035, where n is an integer equal to one less than the quantity of voltage threshold levels. As described herein, a weak decision range 1015 may include a voltage range in which read information for different voltage threshold values are likely to overlap (e.g., such that a threshold network may be used to classify the read information as one of the two associated neighboring values, for improved accuracy and reliability).

According to some example embodiments, the HD thresholds 1005, the strong decision ranges 1010 and/or the weak decision ranges 1015 may vary between memory cells (and/or word-lines) of the NVM 220 and may be stored in the memory 614 in association with indices of the different memory cells (and/or word-lines), but some example embodiments are not limited thereto. According to some example embodiments, the HD thresholds 1005, the strong decision ranges 1010 and/or the weak decision ranges 1015 may be a design parameter(s) determined through empirical study.

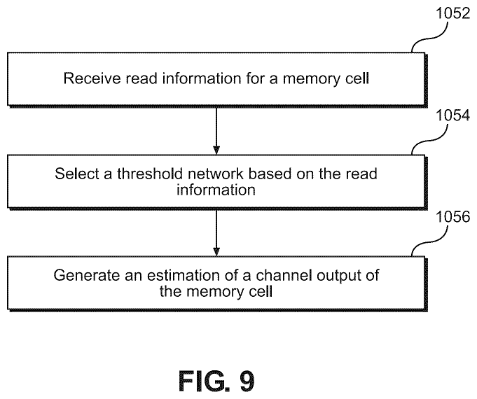

FIG. 9 illustrates a method for generating a correct (e.g., pre-retention) voltage threshold level of a memory cell using the plurality of threshold networks 1020, according to some example embodiments.

Referring to FIG. 9, in operation 1052, a voltage of one or more memory cells is detected using processing circuitry (e.g., the CPU 612 and/or the control logic 320). According to some example embodiments, operation 1052 may be the same as or similar to operation 552 discussed in connection with FIG. 5. According to some example embodiments, in operation 1054, the CPU 612 may select a threshold expert among the plurality of threshold networks 1020 (e.g., the plurality of ANNs) based on the voltage of the one or more memory cells. According to some example embodiments, in scenarios in which the first codeword includes voltages for all of the memory cells of a target word-line, operations 1054 (and operation 1056) may be separately performed with respect to each respective memory cell of the target word-line). For example, the CPU 612 may select a threshold expert corresponding to a weak decision range 1015 that includes the voltage detected in operation 1052 (e.g., a threshold expert corresponding to a weak decision range 1015 that includes the voltage detected for the respective memory cell of the target word-line). According to some example embodiments, in scenarios in which the voltage detected in operation 1052 does not fall within any of the weak decision ranges 1015 (e.g., in scenarios in which the voltage detected in operation 1052 falls within one of the strong decision ranges 1010), the CPU 612 may perform the ECC operation on the detected voltage (e.g., similar to operation 554 discussed in association with FIG. 5) without processing the detected voltage through the plurality of threshold networks 1020.

According to some example embodiments, in operation 1056, the CPU 612 may input the detected voltage (e.g., for the respective memory cell of the target word-line) into the selected threshold expert (e.g., a selected ANN among the plurality of ANNs of the ML algorithm 616) along with the at least one other feature as discussed above. The selected threshold expert may generate an estimate of a correct (e.g., pre-retention) voltage threshold level of the one or more memory cells (e.g., of the respective memory cell of the target word-line) based on these inputs. For example, as discussed above, the selected threshold expert may output an LLR (e.g., for the respective memory cell of the target word-line). The ECC decoding circuit 520 may be configured to determine the correct (e.g., pre-retention) cell voltage(s) (e.g., for the respective memory cell of the target word-line) based on the LLR.

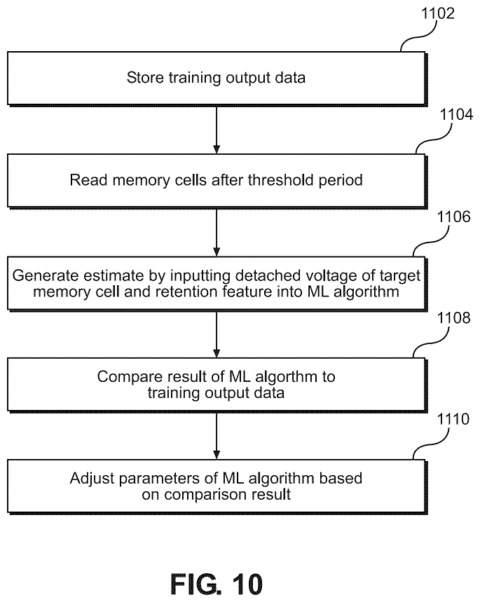

FIG. 10 illustrates a method for training the ML algorithm 616, according to some example embodiments.

Referring to FIG. 10, the ML algorithm 616 may be trained to output an estimated (e.g., pre-retention) voltage threshold level of a memory cell based on input of a detected voltage (e.g., post retention voltage) of the memory cell and the at least one other feature. According to some example embodiments, the operations of FIG. 10 may be performed by processing circuitry. For example, the method for training the ML algorithm 616 may be performed by processing circuitry (e.g., the CPU 612). According to some example embodiments, the operations of FIG. 10 may be performed by the storage device 600, but some example embodiments are not limited thereto. For example, according to some example embodiments, the operations of FIG. 10 may be performed using a training storage device different from the storage device 600. In such circumstances, the training storage device may be implemented using hardware (e.g., training memory cells, memory, etc.) and/or processing circuitry (e.g., CPU, ECC encoding circuit, ECC decoding circuit) that is the same as or similar to corresponding components of the storage device 600. For example, the ML algorithm 616 may be trained using an array of training memory cells that may be the same as or similar to the NVM 220. Detailed descriptions of these components may be omitted with respect to the training storage device to reduce redundancy.

According to some example embodiments, in operation 1102, training output data may be stored (e.g., programmed) to the training memory cells. According to some example embodiments, the training output data may be pseudo-random, but this is merely an example and some example embodiments are not limited thereto. For example, the training output data may be predefined (or given) data set. According to some example embodiments, the training output data may be known, and thus, may be used as an absolute truth for feedback adjustment of the ML algorithm 616 as will be discussed further below. According to some example embodiments, the training output data may be processed by a training ECC encoding circuit, that may be the same as or similar to the ECC encoding circuit 510, before the processed data is stored to the training memory cells. The training output data may be stored to more training memory cells than a target memory cell (or a target memory word-line), thereby providing data for use as the at least one other feature and/or multiple iterations of the training method.

According to some example embodiments, in operation 1104, the training memory cells may be read. According to some example embodiments, operation 1104 may be performed after a threshold period of time has elapsed such that retention effects would have caused a shift in the pre-retention voltage with which the training memory cells were programmed in operation 1102. Alternatively or additionally, operation 1104 may be performed after a threshold quantity of operations (e.g., read, program and/or erase operations) of the training memory cells and/or memory cells adjacent to the training memory cells. The information read from the training memory cells in operation 1104 may include the detected voltage (e.g., post retention voltage) of a target memory cell and the at least one retention feature.

For example, the at least one retention feature may include the programming pulse read voltages, the post-erasure voltage, and/or the neighbor voltages as discussed above in connection with FIG. 6. The at least one retention feature may also include one or more among a hard decision threshold (e.g., for a target word-line and/or a target memory cell), a soft decision threshold (e.g., for a target word-line and/or a target memory cell), and/or an index (e.g., of a target word-line and/or target memory cell). The programming pulse read voltages may include voltages for an entire target word-line of memory cells, or only voltages for a target memory cell. The post-erasure voltage may include voltages for an entire target word-line of memory cells, or only a voltage for a target memory cell. The neighbor voltages may include voltages for one or more entire neighbor word-lines (or bit-lines) of memory cells, or only voltages for one or more WL neighbor memory cells (or BL neighbor memory cells).

According to some example embodiments, each iteration of the method of FIG. 10 may be performed with respect to only a single target memory cell, but some example embodiments are not limited thereto. For example, each iteration of the method of FIG. 10 may be performed with respect to a plurality of target memory cells (e.g., all of the memory cells of a target word-line). The operations discussed in connection with FIG. 10 will mainly be described with reference to only a single target memory cell for simplicity of description.

In operation 1106, the detected voltage of the target memory cell and the at least one retention feature detected in operation 1104 may be input into the ML algorithm 616 to generate an estimated correct (e.g., pre-retention voltage) of the target memory cell. As such, the detected voltage of the target memory cell and the at least one retention feature detected in operation 1104 may be referred to as training input data of the ML algorithm 616. According to some example embodiments, the training input data input to the ML algorithm 616 in operation 1106 may include only a subset of the information detected in operation 1104. For example, in a scenario in which the detected voltage of the target memory cell does not fall within any of the weak decision ranges 1015 (e.g., in scenarios in which the voltage falls within one of the strong decision ranges 1010), or is used to perform a successful ECC operation (e.g., similar to operation 554 discussed above), the information detected in operation 1104 may be discarded (or stored) without performing operation 1106.

As discussed above, the output of the ML algorithm 616 may be in the form of one or more LLRs. In scenarios in which the ML algorithm 616 is implemented using only a single ANN trained to output a plurality of LLRs, processing circuitry (e.g., the CPU 612) may be used to generate only one LLR from among the plurality of LLRs (e.g., by determining a difference between the two highest LLRs). In scenarios in which the ML algorithm 616 is implemented using a plurality of ANNs, each ANN trained to distinguish between a pair of voltage threshold levels, operation 1106 may include selecting only a single ANN corresponding to a weak decision range 1015 into which the detected voltage of the target memory cell falls. This selection may be performed using processing circuitry (e.g., the CPU 612), and the detected voltage of the target memory cell and the at least one other feature detected in operation 1104 may be input into only the selected ANN from among the plurality of ANNs.

In operation 1108, the LLR output by the ML algorithm 616 may be compared to the training output data stored to the training memory cells in operation 1102. As noted above, the training output data may be known, and thus, may be used as an absolute truth for feedback adjustment of the ML algorithm 616. According to some example embodiments, the comparison of operation 1110 may include calculating the cross-entropy between the LLR and the training output data for the target memory cell. For example, the calculation of the cross-entropy may include calculating a magnitude of the cross-entropy between the LLR and the training output data for the target memory cell. According to some example embodiments, the cross-entropy between the LLR and the training output data may serve as a loss function for training the ML algorithm 616,

In operation 1110, parameters of the ML algorithm 616 may be adjusted based on a result of the comparison performed in operation 1108 (e.g., based on the cross-entropy and/or the magnitude of cross-entropy). For example, the cross-entropy calculated in operation 1108 one or more weights and/or biases of the ANN(s) used to implement the ML algorithm 616 may be adjusted. In scenarios in which the ML algorithm 616 is implemented using only a single ANN, the parameters of that single ANN may be adjusted in operation 1110. In scenarios in which the ML algorithm 616 is implemented using a plurality of ANNs, only the parameters of the ANN selected in operation 1106 may be adjusted.

According to some example embodiments, the operations of the method discussed in connection with FIG. 10 may be repeated. For example, these operations may be repeated until the ML algorithm 616 is trained to provide for a correct ECC result at a rate greater than or equal to a threshold rate.

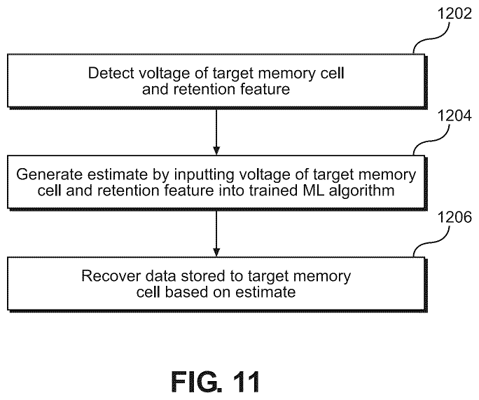

FIG. 11 illustrates a method for recovering data stored to a target memory cell, according to some example embodiments.

Referring to FIG. 11, depicted is a flowchart of a method for recovering data stored to a target memory cell. The method may be performed by processing circuitry. For example, the method may be performed by an equalizer device (e.g., the CPU 612) included in a storage device (e.g., the storage device 600). The storage device may be included in a storage system (e.g., the host storage system 60).

In operation 1202, a post-retention voltage of a target memory cell and at least one retention feature may be detected. According to some example embodiments, the at least one retention feature may include programming pulse read voltages or a post-erasure voltage (e.g., as described in connection with FIG. 6 above). For example, the at least one retention feature may include the programming pulse read voltages. Alternatively or additionally, the at least one retention feature may include the post-erasure voltage (e.g., the partial-erasure voltage or the full-erasure voltage). As discussed in connection with FIG. 6, the programming pulse read voltages may include voltages of the target memory cell detected between a sequence of programming pulses applied to the target memory cell, and the post-erasure voltage may be a voltage of the target memory cell detected after the target memory cell is erased.

According to some example embodiments, the at least one retention feature may include both the programming pulse read voltages and the post-erasure voltage, but some example embodiments are not limited thereto. For example, the at least one retention feature may include the programming pulse read voltages, the post-erasure voltage and/or the neighbor voltages, and/or the hard decision threshold (e.g., for a target word-line and/or a target memory cell), the soft decision threshold (e.g., for a target word-line and/or a target memory cell), and/or an index (e.g., of a target word-line and/or target memory cell). According to some example embodiments, the at least one retention feature may include both the programming pulse read voltages and the post-erasure voltage, and may further include a voltage of a memory cell on a neighbor word-line adjacent to a target word-line, the target word-line including the target memory cell. According to some example embodiments, in scenarios in which the at least one retention feature includes both the programming pulse read voltages and the post-erasure voltage, operation 1202 may include detecting the programming pulse read voltages before detecting the post-erasure voltage(s).

Also, while operation 1202 refers to a target memory cell the operations of the method discussed in connection with FIG. 11 are not necessarily limited to only one target memory cell. For example, according to some example embodiments, operation 1202 (and the remaining operations of FIG. 11) may be performed with respect to a plurality of target memory cells (e.g., all of the memory cells of a target word-line). According to some example embodiments, in scenarios in which the first codeword includes voltages for all of the memory cells of a target word-line, all of these voltages (e.g., post-retention voltages) and all of the retention features corresponding to these memory cells may be detected in operation 1202.

In operation 1204, a pre-retention voltage estimate of the target memory cell may be generated by inputting the post-retention voltage and the at least one retention feature into a trained machine learning algorithm (e.g., the ML algorithm 616). As discussed above, the trained machine learning algorithm may be implemented using a plurality of artificial neural networks (ANN). According to some example embodiments, operation 1204 may also include selecting a first ANN among the plurality of ANNs based on the post-retention voltage of the target memory cell, and generating the pre-retention voltage estimate by inputting the post-retention voltage and the at least one retention feature into the first ANN. According to some example embodiments, in scenarios in which the first codeword includes voltages for all of the memory cells of a target word-line, operation 1204 may include inputting the post-retention voltage and the at least one retention feature for each respective memory cell on the target word-line into the trained machine learning algorithm to obtain a pre-retention voltage estimate of that respective memory cell.

In operation 1206, the data stored to the target memory cell may be recovered based on the estimated pre-retention voltage. For example, the ECC decoding circuit 520 may correct one or more errors corresponding to the post-retention voltage using the output of the ML algorithm 616 (e.g., the estimated pre-retention voltage of the target memory cell). According to some example embodiments, in scenarios in which the first codeword includes voltages for all of the memory cells of a target word-line, the ECC decoding circuit 520 may separately correct one or more errors based on the pre-retention voltage estimates of each respective memory cell, but some example embodiments are not limited thereto. According to some example embodiments, the pre-retention voltage estimates of each respective memory cell of the target word-line may be combined (e.g., concatenated) to for the second codeword, and the ECC decoding circuit 520 may correct one or more errors in the second codeword. According to some example embodiments, the data stored to the target memory cell may include three or more bits of data. According to some example embodiments, the operations 1202, 1204 and 1206 may be repeated with respect to another target memory cell (or another target word-line).

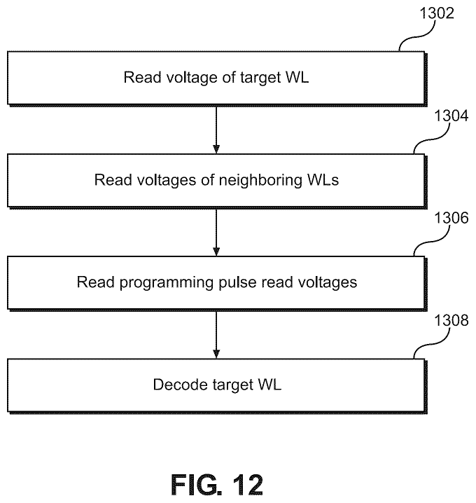

FIG. 12 illustrates a method for recovering data stored to a target word-line based on the programming pulse read voltages and the neighbor voltages, according to some example embodiments.

Referring to FIG. 12, depicted is a flowchart of a method for recovering data stored to a target word-line based on the programming pulse read voltages and the neighbor voltages. The method may be performed by processing circuitry. For example, the method may be performed by an equalizer device (e.g., the CPU 612) included in a storage device (e.g., the storage device 600). The storage device may be included in a storage system (e.g., the host storage system 60).

In operation 1302, a voltage of a target word-line may be read. For example, the respective voltage of each memory cell on the target word-line may be detected. In operation 1304, voltages of neighboring word-lines (e.g., the neighbor voltages) may be read. For example, the respective voltage of each memory cell on the neighboring word-lines (with respect to the target word-line) may be detected. In operation 1306, a sequence of programming pulses and voltage reads are applied to the target word-line to obtain the programming pulse read voltages. For example, the intermediate reads between some of the programming pulses may be used to detect a respective plurality of programming pulse read voltages for each memory cell on the target word-line.

In operation 1308, the target word-line may be decoded. For example, the voltage of each respective memory cell in the target word-line may be separately input to the trained ML algorithm 616 along with the at least one retention feature corresponding to that respective memory cell (e.g., the neighbor voltages, for example, voltages of memory cells on neighboring word-lines and/or bit-lines detected in operation 1304, and the programming pulse read voltages for the respective memory cell detected in operation 1306). The output of the trained ML algorithm 616 (e.g., with respect to each respective memory cell in the target word-line) may be decoded by the ECC decoding circuit 520 to recover the data originally stored (e.g., pre-retention data) in the target word-line. According to some example embodiments, as discussed above, the ML algorithm 616 may be trained to be applied separately with respect to each memory cell of the target word-line but some example embodiments are not limited thereto and the ML algorithm 616 may be trained to be applied to the entire target word-line contemporaneously. According to some example embodiments, the method may further include an operation for rewriting the decoded data to the NVM 220 (e.g., to an empty word-line) to account for the effects of the programming pulses applied in operation 1306 (as discussed in connection with FIG. 6), but some example embodiments are not limited thereto. According to some example embodiments, the operations discussed in connection with FIG. 12 may be repeated with respect to another target word-line.

By including the programming pulse read voltages among the at least one retention feature input into the ML algorithm 616, the BER of the decoding in operation 1308 may be more greatly improved (e.g., decreased) than by relying on the neighbor voltages alone. For example, the below table illustrates the improvement in BER provided by the use of both the neighbor voltages and the programming pulse read voltages relative to the use of only the neighbor voltages. PG-1T

| | | Average BER | Average BER | Average BER | Average BER |
|---|---|---|---|---|---|
| | Average | Improvement - | Improvement - | Improvement - | Improvement - |
| | BER | with | with | with | with |
| | Improvement - | Programming | Programming | Programming | Programming |
| | Neighbor | Pulse Read | Pulse Read | Pulse Read | Pulse Read |
| Bit | Voltages | Voltages (after | Voltages (after | Voltages (after | Voltages (after |
| Index | Alone | 9^{th} Pulse) | 15^{th} Pulse) | 17^{th} Pulse) | 19^{h} Pulse) |
| 0 | 44.74% | 49.17% | 49.17% | 49.50% | 49.77% |
| 1 | 48.26% | 49.86% | 52.29% | 52.89% | 53.06% |
| 2 | 44.92% | 47.85% | 49.62% | 50.40% | 50.74% |
| 3 | 45.46% | 47.07% | 49.04% | 49.54% | 49.64% |
| Average | 45.84% | 48.04% | 50.03% | 50.58% | 50.80% |

As may be seen in the above table, the average BER improvement added by the use of the programming read pulse voltages may be about 5%, higher relative to the use of the neighbor voltages alone, for example, when the voltages are read after the 9^{th}, 15^{th}, 17^{th}, and 19^{th} programming pulses. According to some example embodiments, the bit index may refer to a bit position with respect to a target memory cell (e.g., a 4-bit memory cell) configured to represent 16 states.

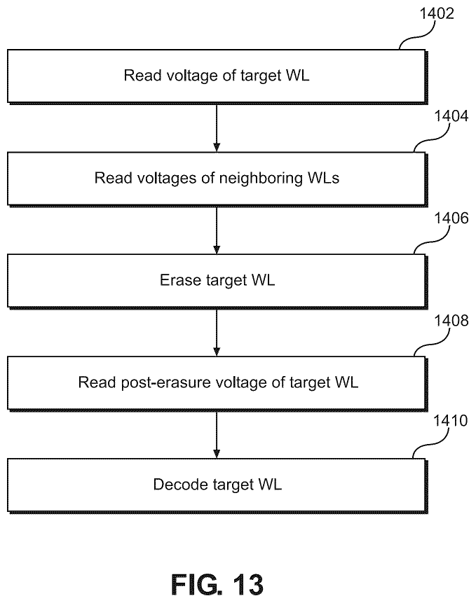

FIG. 13 illustrates a method for recovering data stored to a target word-line based on the post-erasure voltage and the neighbor voltages, according to some example embodiments.

Referring to FIG. 13, depicted is a flowchart of a method for recovering data stored to a target word-line based on the post-erasure voltage and the neighbor voltages. The method may be performed by processing circuitry. For example, the method may be performed by an equalizer device (e.g., the CPU 612) included in a storage device (e.g., the storage device 600). The storage device may be included in a storage system (e.g., the host storage system 60).

In operation 1402, a voltage of a target word-line may be read. For example, the respective voltage of each memory cell on the target word-line may be detected. In operation 1404, voltages of neighboring word-lines (e.g., the neighbor voltages) may be read. For example, the respective voltage of each memory cell on the neighboring word-lines (with respect to the target word-line) may be detected. In operation 1406, the target word-line may be erased (e.g., partially erased or fully erased). According to some example embodiments, the erasure operation may include erasing a target data block (e.g., erasing every memory cell in the target data block) including the target word-line. In operation 1408, the voltage (e.g., the post-erasure voltage) of the target word-line may be read. For example, the respective post-erasure voltage of each memory cell on the target word-line may be detected.

In operation 1410, the target word-line may be decoded. For example, the voltage of each respective memory cell of the target word-line may be separately input to the trained ML algorithm 616 along with the at least one retention feature corresponding to that respective memory cell (e.g., the neighbor voltages, for example, voltages of memory cells on neighboring word-lines and/or bit-lines detected in operation 1404, and the post-erasure voltages for the respective memory cell detected in operation 1408). The output of the trained ML algorithm 616 (e.g., with respect to each respective memory cell in the target word-line) may be decoded by the ECC decoding circuit 520 to recover the data originally stored (e.g., pre-retention data) in the target word-line. According to some example embodiments, as discussed above, the ML algorithm 616 may be trained to be applied separately with respect to each memory cell of the target word-line but some example embodiments are not limited thereto and the ML algorithm 616 may be trained to be applied to the entire target word-line contemporaneously. According to some example embodiments, the method may further include an operation for reading the data of the target word-line (or the data of the target data block) prior to performing operation 1406, and an operation for rewriting the read data of the target word-line (or the data of the target data block) to the NVM 220 (e.g., to an empty word-line or data block) to account for the effects of the erasure process applied in operation 1406 (as discussed in connection with FIG. 6), but some example embodiments are not limited thereto. According to some example embodiments, the operations discussed in connection with FIG. 13 may be repeated with respect to another target word-line.

By including the post-erasure voltage among the at least one retention feature input into the ML algorithm 616, the BER of the decoding in operation 1410 may be more greatly improved (e.g., decreased) than by relying on the neighbor voltages alone. For example, the below table illustrates the increase in BER provided by the use of both the neighbor voltages and the post-erasure voltage relative to the use of only the neighbor voltages.

| | Average BER Improvement - | Average BER Improvement - |
|---|---|---|
| Bit Index | Neighbor Voltages Alone | with Post-Erasure Voltage |
| 0 | 26.19% | 31.48% |
| 1 | 24.69% | 27.45% |
| 2 | 24.68% | 28.42% |
| 3 | 22.62% | 24.57% |
| Average | 24.55% | 27.98% |

As may be seen in the above table, the average BER improvement added by the use of the post-erasure voltage may be about 2-5%, higher relative to the use of the neighbor voltages alone. According to some example embodiments, the bit index may refer to a bit position with respect to a target memory cell (e.g., a 4-bit memory cell) configured to represent 16 states.

According to some example embodiments, the methods discussed in connection with FIGS. 12 and 13 may be combined. For example, operation 1406 may include applying a sequence of programming pulses and voltage reads the target word-line to obtain programming pulse read voltages (as discussed above in connection with operation 1306) before the target word-line is erased. Also, operation 1410 may include separately inputting the voltage of each respective memory cell of the target word-line to the trained ML algorithm 616 along with the at least one retention feature corresponding to that respective memory cell (e.g., the neighbor voltages, the programming pulse read voltages, and the post-erasure voltages for the respective memory cell). By including both of the programming pulse read voltages and the post-erasure voltages among the at least one retention feature input into the ML algorithm 616, the BER of the decoding in operation 1410 may be more greatly improved (e.g., decreased) than by relying on the programming pulse read voltages and the neighbor voltages alone. For example, the below table illustrates the improvement in BER provided by the use of all of the programming pulse read voltages, the post-erasure voltages and the neighbor voltages among the at least one retention feature. The values in the below table are relative to those of the table discussed in connection with FIG. 12.

As may be seen in the above table, the average BER improvement added by the use of all of the programming pulse read voltages, the post-erasure voltages and the neighbor voltages among the at least one retention feature may be about 2%, higher relative to the use of the programming pulse read voltages and the neighbor voltages alone. According to some example embodiments, the bit index may refer to a bit position with respect to a target memory cell (e.g., a 4-bit memory cell) configured to represent 16 states.

Accordingly, through the use of the programming pulse read voltages and/or post-erasure voltages reflecting the changes in the memory cells due to the retention effects, in combination with the ML algorithm, the improved devices and methods may recover the original data stored in the memory cells at a lower BER as compared with the conventional devices and methods. Therefore, the improved devices and methods overcome the deficiencies of the conventional devices and methods to at least reduce data loss without consuming excessive resources (e.g., memory, processor, power, delay, etc.).

According to some example embodiments, a method may be provided for recovering data stored to a target memory cell. For example, the method includes causing the equalizer device to detect a post-retention voltage of a target memory cell and at least one retention feature, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is erased, generating a pre-retention voltage estimate of the target memory cell by inputting the post-retention voltage and the at least one retention feature into a trained machine learning algorithm, and recovering data stored to the target memory cell based on the estimated pre-retention voltage.

According to some example embodiments, a non-transitory computer-readable medium may store instructions that, when executed by processing circuitry of a device, cause the device to detect a post-retention voltage of a target memory cell and at least one retention feature, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is erased, generate a pre-retention voltage estimate of the target memory cell by inputting the post-retention voltage and the at least one retention feature into a trained machine learning algorithm, and recover data stored to the target memory cell based on the estimated pre-retention voltage.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with some example embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (e.g., the memory 614). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particular manner, a function or operation specified in a specific block may be performed differently from the flow specified in a flowchart, flow diagram, etc. For example, functions or operations illustrated as being performed serially in two consecutive blocks may actually be performed concurrently, simultaneously, contemporaneously, or in some cases be performed in reverse order.

It will be understood that when an element is referred to as being “connected” or “coupled” to another element, it may be directly connected or coupled to the other element or intervening elements may be present. As used herein the term “and/or” includes any and all combinations of one or more of the associated listed items.

Although terms of “first” or “second” may be used to explain various components (or parameters, values, etc.), the components (or parameters, values, etc.) are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples.

What is claimed is:

1. An equalizer device, comprising:
processing circuitry configured to cause the equalizer device to
detect a post-retention voltage of a target memory cell and at least one retention feature, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased,
generate a pre-retention voltage estimate of the target memory cell by inputting the post-retention voltage and the at least one retention feature into a trained machine learning algorithm, and
recover data stored to the target memory cell based on the estimated pre-retention voltage.

2. The equalizer device of claim 1, wherein the at least one retention feature includes the programming pulse read voltages.

3. The equalizer device of claim 2, wherein the at least one retention feature includes the programming pulse read voltages and the post-erasure voltage.

4. The equalizer device of claim 1, wherein the at least one retention feature includes the post-erasure voltage.

5. The equalizer device of claim 1, wherein the at least one retention feature further includes a voltage of a memory cell on a neighbor word-line adjacent to a target word-line, the target word-line including the target memory cell.

6. The equalizer device of claim 1, wherein
the trained machine learning algorithm is implemented using a plurality of artificial neural networks (ANNs); and
the processing circuitry is configured to cause the equalizer device to
select a first ANN among the plurality of ANNs based on the post-retention voltage of the target memory cell, and
generate the pre-retention voltage estimate by inputting the post-retention voltage and the at least one retention feature into the first ANN.

7. The equalizer device of claim 1, wherein the data stored to the target memory cell is a multi-level memory cell.

8. A storage device, comprising:
a memory including a plurality of memory cells; and
processing circuitry configured to cause the storage device to
detect a post-retention voltage of a target memory cell and at least one retention feature, the target memory cell being among the plurality of memory cells, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased,
generate a pre-retention voltage estimate of the target memory cell by inputting the post-retention voltage and the at least one retention feature into a trained machine learning algorithm, and
recover data stored to the target memory cell based on the estimated pre-retention voltage.

9. The storage device of claim 8, wherein the at least one retention feature includes the programming pulse read voltages.

10. The storage device of claim 9, wherein the at least one retention feature includes the programming pulse read voltages and the post-erasure voltage.

11. The storage device of claim 8, wherein the at least one retention feature includes the post-erasure voltage.

12. The storage device of claim 8, wherein the at least one retention feature further includes a voltage of a memory cell on a neighbor word-line adjacent to a target word-line in the memory, the target word-line including the target memory cell.

13. The storage device of claim 8, wherein
the trained machine learning algorithm is implemented using a plurality of artificial neural networks (ANNs); and
the processing circuitry is configured to cause the storage device to
select a first ANN among the plurality of ANNs based on the post-retention voltage of the target memory cell, and
generate the pre-retention voltage estimate by inputting the post-retention voltage and the at least one retention feature into the first ANN.

14. The storage device of claim 8, wherein the data stored to the target memory cell is a multi-level memory cell.

15. A storage system, the storage system comprising:
a host configured to output a command to read a target memory cell;
a memory including a plurality of memory cells, the plurality of memory cells including the target memory cell; and
processing circuitry configured to cause the storage system to
detect a post-retention voltage of a target memory cell and at least one retention feature in response to the command, the at least one retention feature including programming pulse read voltages or a post-erasure voltage, the programming pulse read voltages including voltages of the target memory cell detected between a sequence of programming pulses applied to the target memory cell, and the post-erasure voltage being a voltage of the target memory cell detected after the target memory cell is at least partially erased,
generate a pre-retention voltage estimate of the target memory cell by inputting the post-retention voltage and the at least one retention feature into a trained machine learning algorithm, and
recover data stored to the target memory cell based on the estimated pre-retention voltage.

16. The storage system of claim 15, wherein the at least one retention feature includes the programming pulse read voltages.

17. The storage system of claim 16, wherein the at least one retention feature includes the programming pulse read voltages and the post-erasure voltage.

18. The storage system of claim 15, wherein the at least one retention feature includes the post-erasure voltage.

19. The storage system of claim 15, wherein the at least one retention feature further includes a voltage of a memory cell on a neighbor word-line adjacent to a target word-line in the memory, the target word-line including the target memory cell.

20. The storage system of claim 15, wherein
the trained machine learning algorithm is implemented using a plurality of artificial neural networks (ANNs); and
the processing circuitry is configured to cause the storage system to
select a first ANN among the plurality of ANNs based on the post-retention voltage of the target memory cell, and
generate the pre-retention voltage estimate by inputting the post-retention voltage and the at least one retention feature into the first ANN.
